(19) United States
(12) Patent Application Publication
(10) Pub. No.: US 2012/0060900 A1
(43) Pub. Date: Mar. 15, 2012

(54) Cd-Free, Oxide Buffer Layers For Thin Film CIGS Solar Cells By Chemical Solution Deposition Methods

(75) Inventors: Thomas A. Kodenkandath, Highlands Ranch, CO (US); Anne Gatchell, Denver, CO (US); Venugopala R. Basava, Highlands Ranch, CO (US)

(73) Assignee: Ascent Solar Technologies, Inc., Thornton, CO (US)

(21) Appl. No.: 13/227,935

(22) Filed: Sep. 8, 2011

Related U.S. Application Data
(60) Provisional application No. 61/380,994, filed on Sep. 8, 2010.

(51) Int. Cl. H01L 31/042; H01L 31/0272; H01L 31/0224

(52) U.S. Cl. 136/249; 136/256; 438/95; 257/E31.008

(57) ABSTRACT

A process described herein provides an economical means for producing the oxide-based buffer layers using a wet chemical CSD process wherein the desired buffer layer material results from the evaporation of a chemical already containing the material in solution. Thus, no residual liquid chemical elements remain after deposition, and as there is no reaction to create the buffer material, as is the case with CdS CBD, the liquid elements in CSD have sufficiently long shelf life after mixing to as to improve manufacturability and further reduce waste. Furthermore, as there is no in-chamber reaction to create the buffer material solution, there are many options for delivering said solution to the CIGS absorber layer. Finally, as the oxide films for the CdS replacement have inherently better transmission in the blue spectrum, aggressive thinning of films to improve current generation is unnecessary.

### RELATED APPLICATIONS

This application claims the benefit of priority of Provisional Application Ser. No. 61/380,994 filed Sep. 8, 2010, which is incorporated herein by reference.

### BACKGROUND

The present disclosure relates to Cd-free, oxide buffers layers for thin film copper indium gallium di(selenide) (CIGs) solar cells and processes for making and using the same.

### DESCRIPTION OF THE RELATED ART

A solar cell, or photovoltaic cell, is a device that converts solar energy into electrical energy. Solar cells generate voltage, or electrical current, upon irradiation with electromagnetic radiation, such as sunlight. Traditional solar cells are fabricated from silicon-based semiconducting materials. Other solar cells contain polycrystalline material comprising copper indium gallium (di)selenide (CIGS). CIGS is a semiconductor material utilized as a light absorber for photovoltaic cells and is typically present as a polycrystalline thin film.

CIGS-based solar cells operate by absorbing light within the CIGS layer and subsequently generating free electrons with the capacity for movement throughout the CIGS material. Free electrons may diffuse within the CIGS material until reaching an electric field at a junction region. For CIGS devices, junction regions are often formed between the semiconductors CIGS and zinc oxide (ZnO) and may also contain a thin buffer layer containing materials such as cadmium sulfide (CdS) and intrinsic ZnO (i-ZnO). CdS is typically used as a heterojunction partner to CIGS due to certain electrical properties, as well as the synergistic surface effects with a chemical bath deposition (CBD).

CIGS material demonstrates a variety of advantages for solar cells such as displaying a high extinction coefficient that facilitates the fabrication of thin solar cells. For example, reports indicate absorption of about 99% of incident within approximately 1 μm of a CIGS layer. CIGS-based solar cells also show superior performance properties as compared to other semiconducting materials. For example, CIGS material displays one of the highest current densities of known semiconductor material, thereby offering the possibility to produce high current outputs. Moreover, CIGS material shows superior solar-to electrical energy conversion efficiencies with reports indicating greater than 20% conversion efficiencies for CIGS-based solar cells.

Buffer layers for CIGS-based solar cells may also include zinc oxide (ZnO), tin dioxide (SnO₂), and (SnO,S)₂. These buffer layers, however, exhibit low efficiencies, typically between 9%-12%. Moreover, these buffer layers are typically deposited via chemical bath or physical vapor deposition, which are slow, complex, and require multiple chemicals, (R. Mikami et. al, 3^{rd} World Conference of PV Energy Conversion, p. 5198 (2003); D. Hariskos et. al, Proc. 13^{th} European PV-Solar Energy Conference, p. 1995 (1995).

Traditional construction of copper-indium-gallium-(di)selenide (CIGS) solar cells consists of a suitably smooth substrate, a first electrical conductor, a CIGS-based absorber layer, a cadmium sulfide (CdS) buffer layer, and a combination of transparent intrinsic and conductive oxide films that serve as a top electrical contact. While CdS historically has been the buffer layer of choice, there are several compelling reasons for its substitution in the stack, including, but not limited to, blue-spectrum attenuation, limited market acceptance for cadmium (Cd)-containing materials, and additional cost to produce the device in an environmentally benign manner. The nominal chemical bath deposition (CBD) process includes a temperature-sensitive reaction between chemical elements that results in the deposition of the desired CdS material during which the solution is exhausted and must be removed and sequestered from the process chamber. Additional expense for sequestering and filtering Cd from waste streams in the factory associated with wet-chemical CdS processing that is the most common method for CdS deposition also adds to the cost of the final product. CIGS-based solar cells with Cd-free, oxide buffer layers with a chemical solution deposition (CSD) process facilitates inexpensive, facile, and non-toxic buffer layer deposition.

### SUMMARY

The presently disclosed instrumentalities advance the art by providing improved Cd-free, oxide buffer layers for CIGS solar cells having increased energy conversion efficiencies.

### BRIEF DESCRIPTION OF THE FIGURES

FIG. 1A shows a conventional CIGS-based device that contains a CdS buffer layer with FIG. 1B showing expanded detail with respect to a selected area of FIG. 1A.

FIG. 2 shows an example of a CIGS-based device that contains a ZTO buffer layer with FIG. 2A showing expanded detail with respect to a selected area of FIG. 2.

FIG. 3 shows the performance of a CIGS-based device with a CdS layer and a CIGS-based device with a ZTO layer deposited via CSD.

FIG. 4 shows the performance of a CIGS-based device without an i-ZnO layer.

FIG. 5 shows a series of micrographs of ZTO films on CIGS devices.

FIG. 6 shows a CIGS-based device with a ZTO layer and without an i-ZnO layer with FIG. 6A showing expanded detail with respect to a selected area of FIG. 6.

FIG. 7 shows the effects of pre-washing CIGS samples prior to ZTO deposition.

FIG. 8 shows the temperature dependence of a CIGS sample with CdS and a CIGS sample with ZTO.

FIG. 9 shows the performance of a CIGS sample with a ZTO layer and a CIGS sample with a CdS layer for shorter duration deposition dwell time.

FIG. 10 shows various coating systems including a chemical spray (FIG. 10A), slot die coating system (FIG. 10B) and a gravure coating system (FIG. 10C) suitable for ZTO deposition.

### DETAILED DESCRIPTION

The present disclosure provides improved CIGS-based solar cells with Cd-free, oxide buffer layers that facilitate inexpensive, facile, and non-toxic buffer layer deposition. In a preferred embodiment, Cd-free, oxide buffer layers for CIGS-based solar cells may comprise zinc-tin-oxide (ZTO) material. In one embodiment, a CIGS-based solar cell may contain multiple functional layers including a substrate layer, a electrical contact layer, a buffer layer, a CIGS layer and a transparent, conductive layer. In one embodiment, the electrical contact layer contains molybdenum, molybdenum alloy or multilayer metallic films. In various embodiments, the substrate contains glass, polymer such as polyimide, molybdenum, aluminum, copper, and/or stainless steel. In one embodiment, the transparent, conductive layer contains indium tin oxide (ITO), which alternatively may include CuAlO₂, SnO—F, and/or Ag.

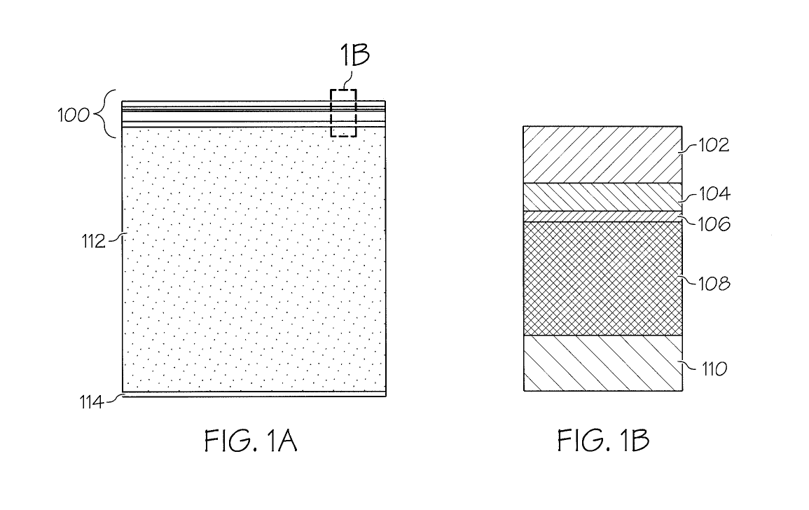

FIG. 1 shows a conventional CIGS device 100 positioned atop a polyimide substrate 112 and a back-side layer 114. In one embodiment, the back-side layer 114 serves to balance film stresses from the device 100 and to provide the substrate 112 with basic environmental protection prior to encapsulation. In one embodiment, this back-side layer contains molybdenum, other metals, or metal oxides. FIG. 1A is an expanded view of the CIGS device 100 at an increased proportional scale. FIG. 1A contains multiple layers comprising transparent, conductive layer 102, i-ZnO 104, CdS 106, CIGS 108, and electrical contact layer 110. In one embodiment, the transparent, conductive layer contains indium tin oxide (ITO), which alternatively may include CuAlO2, SnO—F, and/or Ag. Electrical contact layer 110 serves as a base electrode due to its electrical conductivity and work function. In one embodiment, the electrical contact layer 110 contains molybdenum, molybdenum alloys, or multilayer films that function as an electrical conductor as a whole. Where sub-bandgap light transmission through the CIGS film 108 is desired, electrical contact layer 110 may also contain metallic oxides that are transparent in the desired portions of the spectrum. The CdS buffer layer 106 and the CIGS absorber layer 108 comprise the n and p-type semiconductors needed to generate the requisite electrical field necessary for proper photovoltaic operation. In this embodiment, the transparent conductive layer 102 and the electrical contact layer 110 function as the negative and positive terminals, respectively, of the resultant photovoltaic device. The transparent conductive layer may be made of, for example, indium tin oxide, CuAlO₂, SnO—F, and/or Ag.

In the embodiment illustrated in FIG. 1A, light hitting the transparent conductive layer 102 is transmitted through to the underlying i-ZnO film 104. This light is then transmitted through the CdS buffer layer 106 to the CIGS absorber layer 108. Energy from the light reaching the absorber layer 108 is either converted to electricity, reflected, or is converted to waste energy (heat). Each layer through which the light passes, 102, 104, and 106, each absorb some portion of the spectrum, although 102 and 104 are ideally highly transparent in the visible spectrum to which the CIGS absorber layer 108 is sensitive. Depending upon the buffer layer composition and/or thickness, a portion of the spectrum passing through buffer layer 106 may be attenuated and thus not available for conversion in the absorber layer 108.

Another complication of the embodiment shown in FIG. 1A is the nature of the CdS buffer layer. While layers 102 and 104 are relatively transparent within the light spectrum to which the absorber layer 108 is responsive, most embodiments of the CdS buffer layer 106 are not. Attenuation in the blue portion of the spectrum restricts the light available in this portion of the spectrum from reaching the absorber layer 108; thus, CdS layers are often kept as thin as possible (approximately 200 Å-300 Å) to attenuate the least amount of light while providing the requisite electrical function to the device. Consequently, the intrinsic layer 104 is often employed to aid in preventing electrical shorting, or shunts through pinholes that may be present in excessively-thinned CdS buffer layer 106. While the presence of the i-ZnO does not necessarily provide a mechanism for performance reduction in as-fabricated devices, the hygroscopic nature of the zinc oxide system and its links to moisture-related degradation in CIGS devices can provide a mechanism for long-duration failures of CIGS photovoltaic devices 100 in the field. Thus, reduction in the intrinsic ZnO components 104 in the device can be advantageous as well, but not at the expense of attenuation from a thicker CdS buffer layer 106.

Advantageously, ZTO material does not attenuate light within the blue portion of the spectrum, thereby providing benefits such as film thickness independence. For example, when using ZTO the light attenuation within the spectrum to which CIGS absorber layer 108 is sensitive is not an issue and, as such, a thicker buffer layer comprised of ZTO will not be an issue similar to the CdS buffer film 106 noted earlier. Thus, a ZTO buffer film may be sufficiently thick so as to eliminate potential pinholes and other poor deposition coverage issues that may be related to device shunting.

In some embodiments, utilizing thick ZTO layers within a Cd-free CIGS-based solar cell may permit elimination of i-ZnO layer. In one nonlimiting example, a highly efficient CIGS solar cell is generated by using a thick ZTO film and eliminating an i-ZnO layer, thereby eliminating the possibility of water vapor-related environmental failures. Elimination of water vapor-related environmental failures may provide a robust device with increased longevity. In one embodiment, eliminating an i-ZnO layer and using a ZTO layer permits use of Cd-free CIGS-based solar cells for building-integrated photovoltaic. In another embodiment, using a ZTO layer facilitates the replacement of an i-ZnO cathode with an ITO cathode to improve deposition speed and throughput.

In some embodiments, the application of Cd-free, oxide buffer to CIGS absorbers may occur through chemical solution deposition, spin-coating, or roll-to-roll (R2R) coating system employing a chemical spray, slot-die or gravure printing approach. In a preferred embodiment, the zinc-tin-oxide material is applied to CIGS material via spin-coating in non-commercial applications. These application methods are facile and rapid without producing excessive chemical waste. In one embodiment, the application of Cd-free, oxide buffer to CIGS absorbers occurs at temperatures less than 300° C.

In one example, a zinc-tin based material is applied to a CIGS absorber with a formula:

Zn₍₁₋ₓ₎Sn₍ₓ₎

Where x may range from 0.0 to 0.75 and more preferably ranges from 0.25 to 0.5. In various embodiments, x may range from: 0.0<x≦0.25, 0.25≦x≦0.33, 0.33≦x≦0.5, 0.5≦x≦0.75. In one embodiment, x=0.25. Alternately, zinc-tin based material may also be doped with cadmium-based material, such as cadmium sulfide. Other nonlimiting examples of dopants for zinc-tin based material include Ga, In, Mg, F, and Cl. In one example, dopants may be present within the zinc-tin based material between 0 weight % and 3 weight %.

The following descriptions will show and describe, by way of non-limiting examples, improved CIGS solar cells with Cd-free, oxide buffer layers. The following nonlimiting examples describe preparation and characterization of CIGS solar cells with Cd-free, oxide buffer layers. It is to be understood that these examples are provided by way of illustration and should not be unduly construed to limit the scope of what is disclosed herein.

### Example 1

### Preparation and Characterization of Cigs Solar Cells with Cd-Free, Oxide Buffer Layers

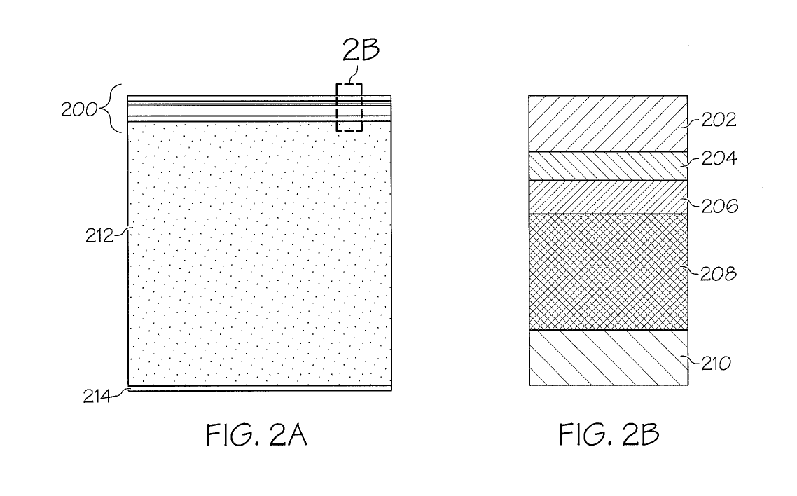

This example teaches by way of illustration, not by limitation, preparation and characterization of CIGS solar cells with Cd-free, oxide buffer layers. A metal-organic solution of Zn-Acetate and Sn-chloride is made in Methanol/Tri-Fluoro Acetic Acid solvent system. The concentration of the metal-organic solution of Zn-Acetate and Sn-chloride is varied from 0.1 M to 0.5 M. Also, composition x, in Zn(1−x)Sn(x), is varied from 0.0, 0.25, 0.33, 0.5 and 0.75. These solutions were applied to CIGS absorbers by spin-coating at various revolutions per minute (RPMs) for 30 seconds. The deposited films were first dried at approximately 150° C. and subsequently processed at approximately 200°-300° C. and at ambient conditions for a duration between 3-30 minutes. The samples were then cooled to room temperature. Additional iZnO and ITO layers were subsequently deposited by physical vapor deposition (PVD) under a base pressure ˜1.5×10⁻⁵ Torr, deposition pressure ˜3.5×10⁻⁵ Torr in 25% Ar/O₂ mixture under a flow rate of ˜10-50 sccm. For ITO, the depositions conditions also included water under a flow rate of 0.0-1.0 sccm methods (FIG. 2), followed by Ag-grids either by e-beam or screen-printing. The image in FIG. 2 is provided for purposes of illustration and may not be true to scale. FIG. 2A is an expanded view of the CIGS device 200 at an increased proportional scale. FIG. 2A contains consecutive layers comprising conductive, transparent layer 202, i-ZnO 204, ZTO 206, CIGS 208, and electrical contact layer 210. In one embodiment, conductive, transparent layer 202 is ITO, which alternatively may include CuAlO2, SnO—F, and/or Ag. Electrical contact layer 110 serves as a base electrode due to its electrical conductivity and work function. In one embodiment, the electrical contact layer 110 contains molybdenum, molybdenum alloys, or multilayer films that function as an electrical conductor as a whole. The CIGS device of FIG. 2 is positioned atop a polyimide layer 212 and an back-side layer 214. In one embodiment, the back-side layer 214 serves to balance film stresses from the device 200 and to provide the substrate 212 with basic environmental protection prior to encapsulation. In one embodiment, this back-side layer contains molybdenum, other metals, or metal oxides. After fabrication, these devices were tested for current-voltage characteristics (I-V test) under 1.5 AM.

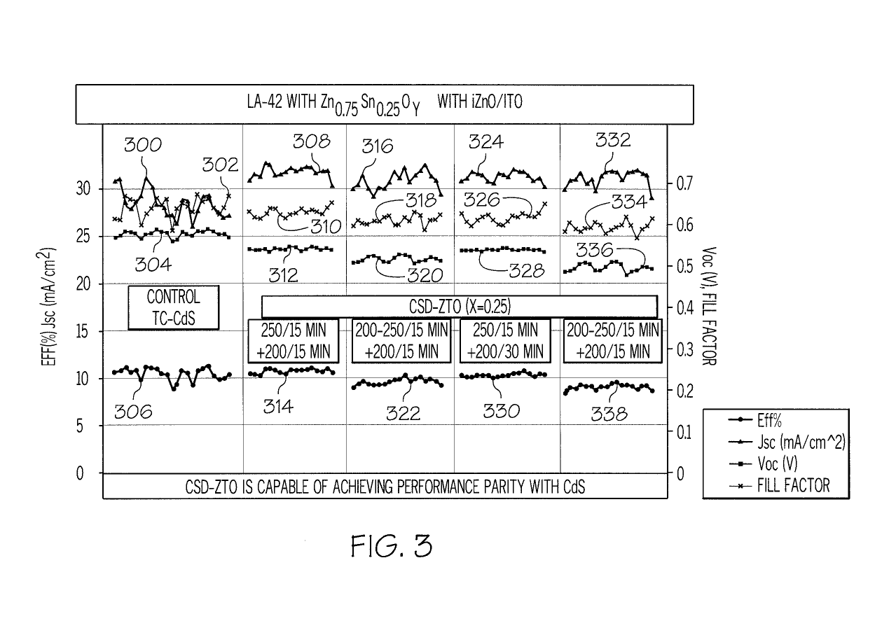

FIG. 3 shows comparison between a CIGS-based device containing a CdS layer and a CIGS-based device containing a ZTO layer, with both CIGS-based devices containing an i-ZnO layer and a ITO layer. The graphs in FIG. 3 show the open circuit voltage (VOC) (units of Volts (V)), the fill factor, the percent solar-to electrical energy conversion efficiencies (% eff), and the current density (units mA/cm³). VOC refers to the difference in electrical potential between two terminals within a device without an external load. Fill factor refers to the ratio of actual maximum obtainable power to actual power.

Curve 300, curve 302, curve 304, and curve 306 display the current density, the fill factor, the VOC, and the conversion efficiencies, respectively, for CIGS-based device containing a CdS layer. Curve 308, curve 310, curve 312, and curve 314 display the current density, the fill factor, the VOC, and the conversion efficiencies, respectively, for a CIGS-based device containing ZTO layer (with composition Zn₍₁₋ₓ₎Sn₍ₓ₎ and x=0.25) applied via chemical solution deposition (CSD), processed at 250° C. at ambient conditions for 15 minutes and post-annealed at 200° C. for 15 minutes. Curve 316, curve 318, curve 320, and curve 322 display the current density, the fill factor, the VOC, and the conversion efficiencies, respectively, for a CIGS-based device containing ZTO layer (with composition Zn₍₁₋ₓ₎Sn₍ₓ₎ and x=0.25) applied via CSD, processed at between 200-250° C. at ambient conditions for 15 minutes and post-annealed at 200° C. for 15 minutes. Curve 324, curve 326, curve 328, and curve 330 display the current density, the fill factor, the VOC, and the conversion efficiencies, respectively, for a CIGS-based device containing ZTO layer (with composition Zn₍₁₋ₓ₎Sn₍ₓ₎ and x=0.25) applied via CSD, processed at 250° C. at ambient conditions for 15 minutes and post-annealed at 200° C. for 30 minutes. Curve 332, curve 334, curve 336, and curve 338 display the current density, the fill factor, the VOC, and the conversion efficiencies, respectively, for a CIGS-based device containing ZTO layer (with composition Zn₍₁₋ₓ₎Sn₍ₓ₎ and x=0.25) applied via CSD, processed between 200-250° C. at ambient conditions for 15 minutes and post-annealed at 200° C. for 15 minutes. Overall, the curves for the CIGS-based device containing a ZTO layer compare favorable to the curves for the CIGS-based device containing a CdS layer. Overall, the devices show performance parity with chemical bath deposited CdS layers after post-annealing at approximately 200° C. for 15-30 minutes (FIG. 3).

### Example 2

### Preparation and Characterization of CIGS Solar Cells without an i-ZnO Buffer Layer

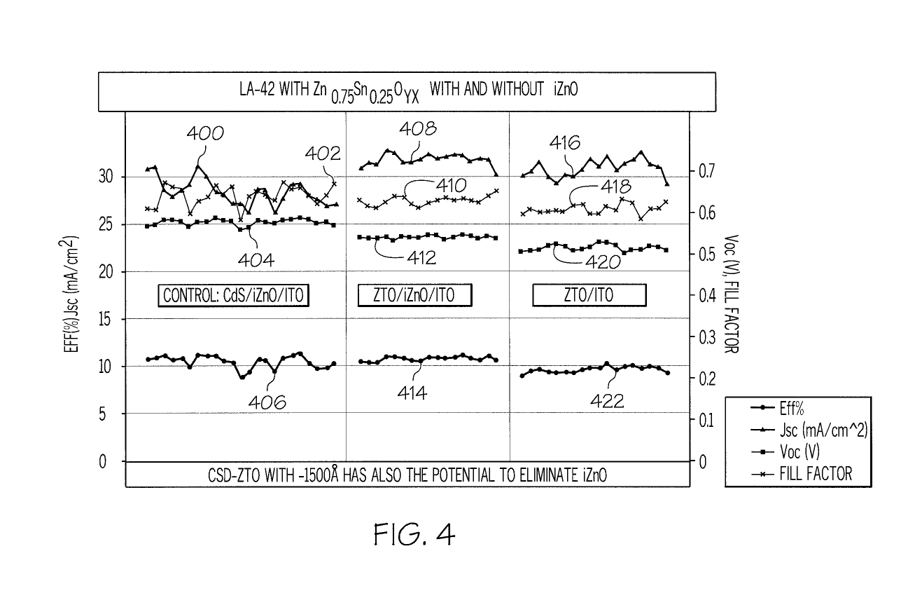

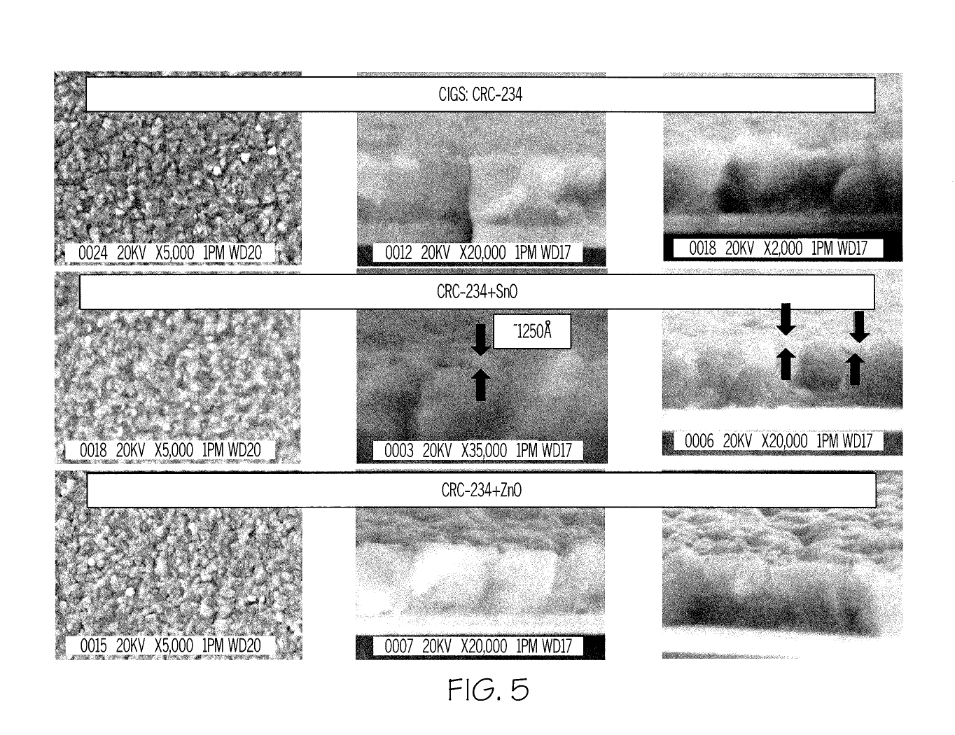

This example teaches by way of illustration, not by limitation, preparation and characterization of CIGS solar cells with a Cd-free, oxide buffer layer and without an i-ZnO buffer layer. Elimination of the i-ZnO buffer layer eliminates moisture sensitivity of the CIG device. The need for an additional i-ZnO layer is eliminated by utilizing thicker ZTO layers, as shown in FIG. 4. FIG. 4 compared a CIGS-based device with a CdS layer, a CIGS-based devices with ZTO layers. Curve 400, curve 402, curve 404, and curve 406 display the current density, the fill factor, the VOC, and the conversion efficiencies, respectively, for a CIGS-based device containing a CdS layer. Curve 408, curve 410, curve 412, and curve 414 display the current density, the fill factor, the VOC, and the conversion efficiencies, respectively, for a CIGS-based device containing a ZTO layer (with composition Zn_{0.75}Sn_{0.25}O_{y}), an i-ZnO layer and an ITO layer. Curve 416, curve 418, curve 420, and curve 422 display the current density, the fill factor, the VOC, and the conversion efficiencies, respectively, for a CIGS-based device containing a ZTO layer (with composition Zn_{0.75}Sn_{0.25}O_{y}) and an ITO layer. FIG. 5 shows a series of micrographs of ZTO films on CIGS devices.

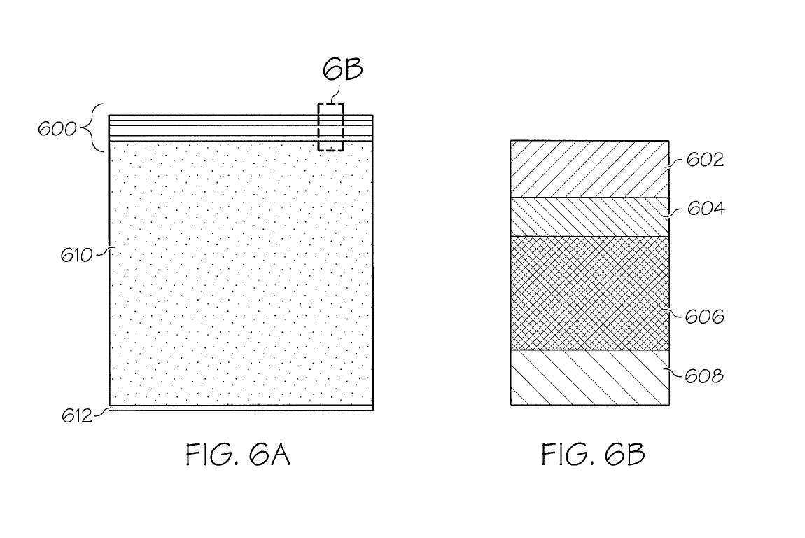

The image in FIG. 6 is provided for purposes of illustration and may not be true to scale. The CIGS device 600 of FIG. 6 is positioned atop a polyimide layer 610 and a back-side layer 612. In one embodiment, the back-side layer 612 serves to balance film stresses from the device 600 and to provide the substrate 610 with basic environmental protection prior to encapsulation. In one embodiment, this back-side layer contains molybdenum, other metals, or metal oxides. FIG. 6A is an expanded view of the CIGS device 600 at an increased proportional scale. FIG. 6A contains consecutive layers comprising transparent conductive layer 602, ZTO 604, CIGS 606, and electrical contact layer 608. In one embodiment, transparent conductive layer 602 contains ITO, which alternatively may include CuAlO₂, SnO—F, and/or Ag. Electrical contact layer 608 serves as a base electrode due to its electrical conductivity and work function. In one embodiment, the electrical contact layer 110 contains molybdenum, molybdenum alloys, or multilayer films that function as an electrical conductor as a whole.

### Example 3

### Characterization of CIGS Solar Cells with Cd-Free, Oxide Buffer Layers

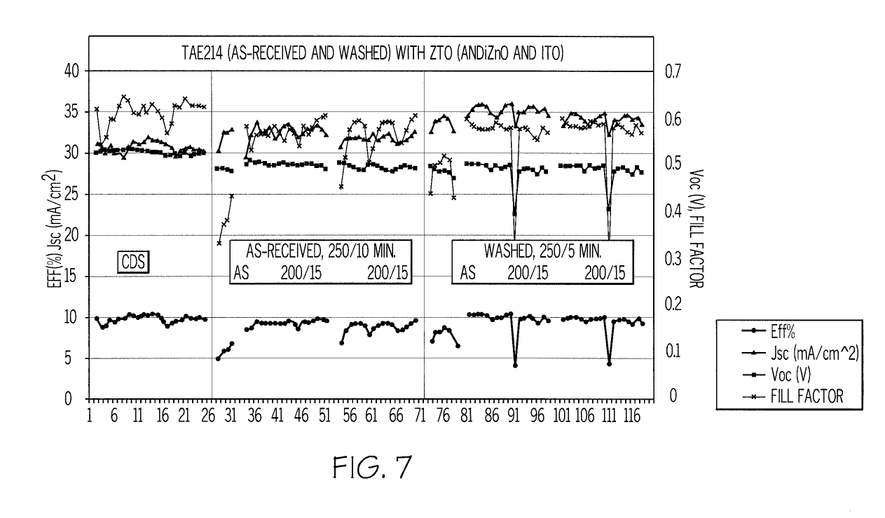

This example teaches by way of illustration, not by limitation, additional characterizations of CIGS solar cells with a Cd-free, oxide buffer layer and without an i-ZnO buffer layer. FIG. 7 shows the effects of pre-washing CIGS samples prior to ZTO deposition. Pre-washing samples consisted of washing in warm water by immersion for 1-2 minutes in order to achieve a consistent surface condition prior to ZTO deposition by removing excess materials, such as sodium, that result from the CIGS fabrication process. Curve 700, curve 702, curve 704, and curve 706 display the current density, the fill factor, the VOC, and the conversion efficiencies, respectively, for a CIGS-based device containing a CdS layer. Curve 708, curve 710, curve 712, and curve 714 display the current density, the fill factor, the VOC, and the conversion efficiencies, respectively, for a CIGS-based device pre-washed at 250° C. for 10 minutes prior to ZTO deposition. Curve 716, curve 718, curve 720, and curve 722 display the current density, the fill factor, the VOC, and the conversion efficiencies, respectively, for a CIGS-based device pre-washed at 250° C. for 5 minutes prior to ZTO deposition. Pre-washing the CIGS samples prior to ZTO deposition affects the current density, the fill factor, the VOC, and the conversion efficiencies, thereby indicating sensitivity to surface conditions.

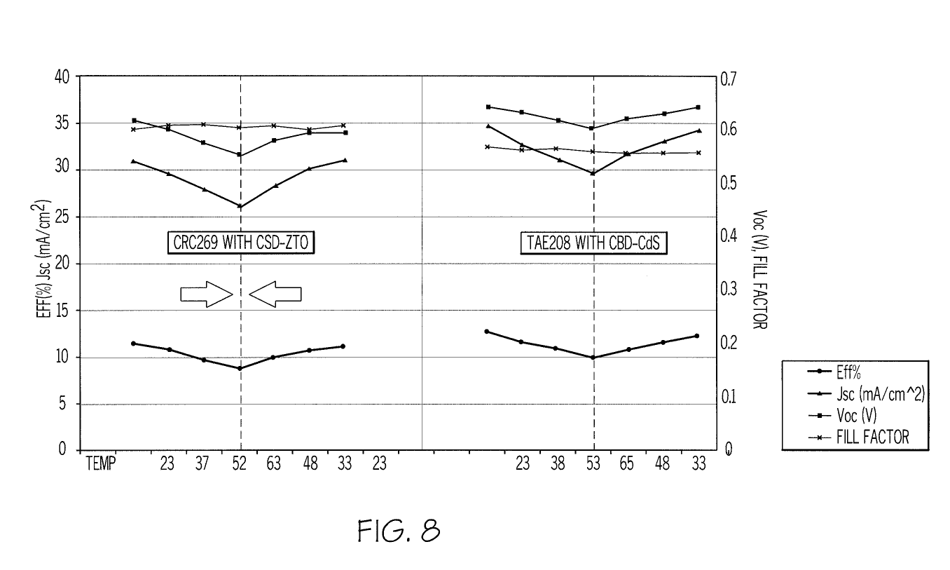

FIG. 8 shows the temperature dependence on a CIGS sample with a CdS layer and a CIGS sample with a ZTO layer. The curves in FIG. 8 show similar hysteresis effects between CIGS samples containing CdS and CIGS samples containing ZTO. Curve 800, curve 802, curve 804, and curve 806 display the current density, the fill factor, the VOC, and the conversion efficiencies, respectively, for a CIGS-based device containing a ZTO layer. Curve 808, curve 810, curve 812, and curve 814 display the fill factor, current density, the VOC, and the conversion efficiencies, respectively, for a CIGS-based device containing a layer.

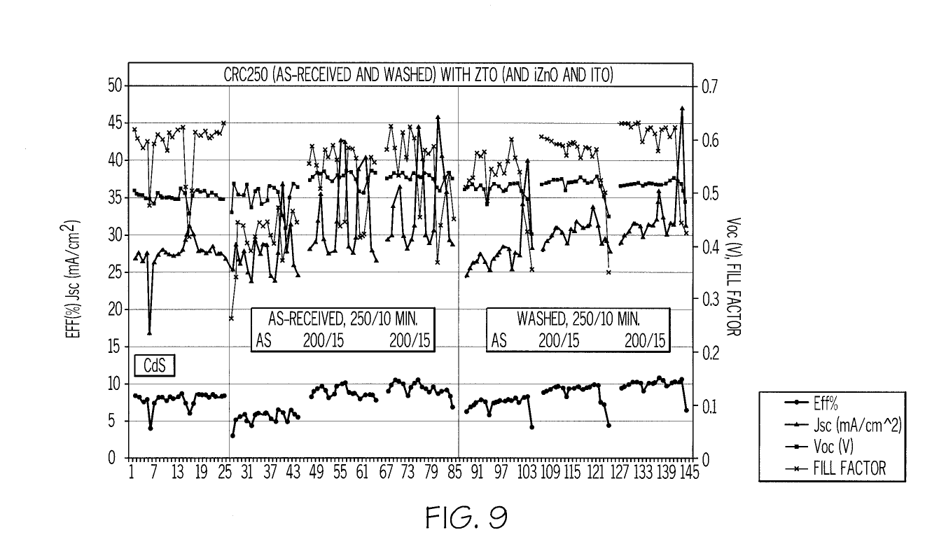

FIG. 9 shows the performance of a CIGS sample with a ZTO layer and a CIGS sample with a CdS layer for shorter duration deposition dwell time. As shown in FIG. 9, a pre-washed sample of CIGS/ZTO at 10 minutes had similar, if not better, properties to the baseline CIGS/CdS. FIG. 9 demonstrates that CIGS samples with ZTO permits shorter dwell time as compared to CdS, thereby improving the throughput capabilities. Curve 900, curve 902, curve 904, and curve 906 display the fill factor, the VOC, the current density, and the conversion efficiencies, respectively, for a CIGS-based device containing a CdS layer. Curve 908, curve 910, curve 912, and curve 914 display the fill factor, the VOC, the current density, and the conversion efficiencies, respectively, for a CIGS-based device containing a ZTO layer without a pre-wash. Curve 916, curve 918, curve 920, and curve 922 display the fill factor, the VOC, the current density, and the conversion efficiencies, respectively, for a CIGS-based device containing a ZTO layer with a pre-wash.

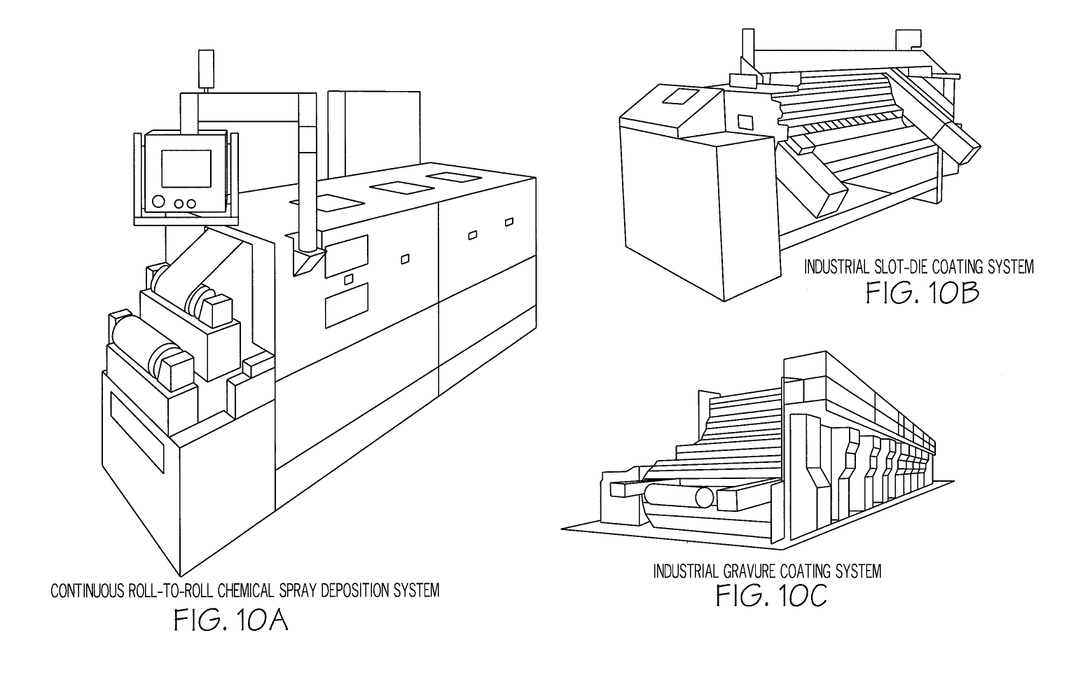

The present disclosure permits ZTO deposition using existing chemical bath deposition (CBD) equipment already in place in FAB1 and FAB2. This equipment utilizes a framed step-and-repeat (e.g. not continuous) deposition process. ZTO is also deposited using a continuous process, such as, but not limited to, ‘Spray’ using a fixed wide spray head or rastering a more focused delivery system, ‘Slot-Die’ using slot die equipment, or ‘Gravure’ using gravure printing apparatus, as shown in FIG. 10. All three processes permit a continuous precision deposition of material can be made with nearly full utilization of materials. This provides a high-yield alternative to chemical bath deposition. Spray, Slot Die and Gravure equipment are commercially available in all scales from R & D to Production.

It will be appreciated that the foregoing embodiments may be adapted for use in cells that are connected by monolithic integration, for example, as described in U.S. Pat. No. 7,994,418 issued to Tandon et al., which is hereby incorporated by reference to the same extent as though fully replicated herein. Other methods of monolithic incorporation are known in the art.

Changes may be made in the above methods and systems without departing from the scope hereof. It should be noted that the matter contained in the above description or shown in the accompanying drawings should be interpreted as illustrative and not in a limiting sense. The following claims are intended to cover all generic and specific features described herein, as well as all statements of the scope of the present method and system and reasonable variations thereof, which, as a matter of language, might be said to fall therebetween.

What is claimed is:

1. A solar cell, comprising:
(a) a substrate that supports a thin film photovoltaic device;
(b) a first electrical contact layer disposed onto the substrate
(c) a light absorbing layer that is disposed onto, and making electrical contact with, the first electrical contact, with the absorber material consisting of copper indium gallium (di)selenide material or alloys thereof;
(d) a zinc-tin based buffer layer that is disposed onto, and making electrical contact with, the absorber layer to form a heterojunction;
(e) a transparent, intrinsic layer disposed onto the buffer layer, and
(f) a transparent, conductive layer disposed onto and making contact with the zinc-tin-oxide material layer

2. The solar cell of claim 1, the substrate comprising at least one material selected from the group consisting of glass, polymer, molybdenum. aluminum, copper, stainless steel.

3. The solar cell of claim 1 wherein the zinc tin oxide material layer is selected from the group of materials having the formula Zn₍₁₋ₓ₎Sn₍ₓ₎ where 0.25≦x≦0.50.

4. The zinc-tin oxide material of claim 3, wherein x=0.25.

5. The solar cell of claim 1, the transparent, conductive layer comprising a material selected from the group consisting of indium tin oxide, CuAlO₂, SnO—F, and Ag.

6. A method for producing a solar cell described in claim 1 comprising:
(a) providing a first electrical contact/CIGS absorber stack, wherein the CIGS absorber is positioned on a substrate;
(b) providing a liquid precursor, wherein the liquid precursor contains zinc and tin;
(c) applying the liquid precursor solution to the CIGS absorber using chemical solution deposition;
(d) drying and annealing the liquid precursor solution.

7. The method of claim 6, wherein chemical solution deposition includes spin-coating roll-to-roll spray, slot-die or gravure coating.

8. A solar cell of claim 2 that includes monolithic integration processing so as to provide multiple cells from a given area

9. A solar cell, comprising:
(a) a substrate that supports a thin film photovoltaic device;
(b) a first electrical contact layer disposed onto the substrate
(c) a light absorbing layer that is disposed onto, and making electrical contact with, the first electrical contact, with the absorber material consisting of copper indium gallium (di)selenide material or alloys thereof;
(d) a zinc-tin based buffer layer that is disposed onto, and making electrical contact with, the absorber layer to form a heterojunction;
(e) a transparent, conductive layer disposed onto and making contact with the zinc-tin-oxide material layer

10. The solar cell of claim 9, the substrate comprising at least one material selected from the group consisting of glass, polymer, molybdenum. aluminum, copper, stainless steel.

11. The solar cell of claim 9 wherein the zinc tin oxide material layer is selected from the group of materials having the formula Zn₍₁₋ₓ₎Sn₍ₓ₎ where 0.25≦x≦0.50.

12. The zinc-tin oxide material of claim 11, wherein x=0.25.

13. The solar cell of claim 9, the transparent, conductive layer comprising a material selected from the group consisting of indium tin oxide, CuAlO₂, SnO—F, and Ag.

14. A method for producing a solar cell described in claim 9 comprising:
(a) providing a first electrical contact/CIGS absorber stack, wherein the CIGS absorber is positioned on a substrate;
(b) providing a liquid precursor, wherein the liquid precursor contains zinc and tin;
(c) applying the liquid precursor solution to the CIGS absorber using chemical solution deposition;
(d) drying and annealing the liquid precursor solution.

15. The method of claim 14, wherein chemical solution deposition includes spin-coating roll-to-roll spray, slot-die or gravure coating.

16. A solar cell of claim 9 that includes monolithic integration providing multiple cells in a given area.
